(19) United States
(12) Patent Application Publication
(10) Pub. No.: US 2015/0104600 A1
(43) Pub. Date: Apr. 16, 2015

(54) TOUCH SENSOR

(71) Applicant: Samsung Electro-Mechanics Co., Ltd., Suwon-si (KR)

(72) Inventors: Kee Su Jeon, Suwon-si (KR); Man Sub Shin, Suwon-si (KR)

(73) Assignee: SAMSUNG ELECTRO-MECHANICS CO., LTD., Suwon-si (KR)

(21) Appl. No.: 14/169,611

(22) Filed: Jan. 31, 2014

(30) Foreign Application Priority Data
Oct. 14, 2013 (KR) 10-2013-0122070

(51) Int. Cl. H05K 5/02

(52) U.S. Cl. CPC H05K 5/0243
USPC 428/38

(57) ABSTRACT

Disclosed herein is a touch sensor, including: a window substrate; and a bezel layer formed along an edge of the window substrate, wherein the bezel layer includes a print layer and a shield layer, wherein the print layer includes titanium dioxide TiO₂ of from 60 to 95 weight %. According to the present invention, titanium dioxide TiO₂ of from 60 to 95 weight % is included in the print layer, which is an element of the bezel layer of the touch sensor, so that whiteness may be improved. Further, the thickness of the print layer is 20 μm or less, so that difficulty in forming electrical connection due to a level difference may be overcome.

### CROSS REFERENCE TO RELATED APPLICATION

This application claims the benefit of Korean Patent Application No. 10-2013-0122070, filed on Oct. 14, 2013, entitled “Touch Sensor,” which is hereby incorporated by reference in its entirety into this application.

### BACKGROUND OF THE INVENTION

1. Technical Field

The present invention relates to a touch sensor.

2. Description of the Related Art

In accordance with the growth of computers using digital technologies, devices assisting computers have also been developed, and personal computers, portable transmitters and other personal information processors execute processing of text and graphics using a variety of input devices such as a keyboard and a mouse.

Consequently, the use of computers is ever-increasing due to rapid transition into an information-oriented society. However, existing keyboards and mouse currently serving as input devices have limits to efficiently operate products. Therefore, required is a device that is simple, less likely to be miss-operated, and easy for everyone to input information.

In addition, techniques for input devices are evolving from a level of realizing general functions into a level considering high reliability, durability, innovation, designing and processing. To this end, a touch sensor has been developed as an input device capable of inputting information such as text and graphics.

Such a touch sensor is mounted on a display of an image display device such as an electronic organizer, a flat panel display device including a liquid crystal display (LCD) device, a plasma display panel (PDP), an electroluminescence (El) element or the like, or a cathode ray tube (CRT) to thereby allow a user to select desired information while viewing the image display device.

Types of touch sensors are classified into a resistive type touch sensor, a capacitive type touch sensor, an electromagnetic type touch sensor, a surface acoustic wave (SAW) type touch sensor, and an infrared type touch sensor. These various types of touch sensors are employed by electronic products depending on factors such as signal amplification, resolution differences, difficulty of designing and processing, optical properties, electrical properties, mechanical properties, resistance to an environment, input characteristics, durability, and economic efficiency. Currently, the resistive type touch sensor and the capacitive type touch sensor are most commonly used.

More recently, however, an operation type of the touch screen module has rapidly changed from the resistive type to the capacitive type, and the touch screen module has also changed from the GFF or GF2 type to a touch integrated with cover window type or on-cell or in-cell type.

Previously, in manufacturing touch sensors, various kinds of colors may be used to form the bezel layer in consideration for esthetics or masking. Inter alia, a white bezel layer is most commonly used as a basic color. In the case of the white color, it is necessary to form a thick film of 20 μm or larger in order to obtain sufficient reflectivity increased by using a white pigment. However, an OCA adhesive layer used for attaching a sensor also needs to be thick so that in a window-integrated type, it may be difficult to form a sensor electrode due to a difference in level.

Patent Document 1 proposes various colors of bezel layers having high transparency in the bezel layer formed along the edge of the mobile digital devices. However, it fails to implement a thin film bezel together with maximum whiteness.

(Patent Document 1) Japanese Patent Laid-Open Publication No. 2011-194799

### SUMMARY OF THE INVENTION

The present invention has been made in an effort to provide a touch sensor employing a white bezel layer, which has improved whiteness by including titanium dioxide TiO₂ in a print layer while making the print layer thin.

Accordingly, titanium dioxide TiO₂ of from 60 to 95 weight % is included in the print layer, which is an element of the bezel layer of the touch sensor, so that whiteness may be improved. Further, the thickness of the print layer is 20 μm or less, so that difficulty in forming electrical connection due to a difference in level may be overcome.

According to a first preferred embodiment of the present invention, there is provided a touch sensor, including: a window substrate; and a bezel layer formed along an edge of the window substrate, wherein the bezel layer includes a print layer and a shield layer, wherein the print layer includes titanium dioxide TiO₂ of from 60 to 95 weight %.

The print layer may include titanium dioxide TiO₂ of from 75 to 90 weight %.

Particle surfaces of the titanium dioxide TiO₂ may be coated with silica SiO₂, aluminum oxide Al₂O₃, zirconium oxide ZrO₂, zinc oxide ZnO or a mixture thereof.

The print layer may include a thermosetting resin or a photo-curable resin of 5 to 40 weight %.

A thickness of the print layer may be less than 20 μm.

The print layer may have luminance L* of 80% or higher in the L*a*b color space adopted by the International Commission on Illumination (CIE).

The print layer may further include a whitening agent.

The shield layer may be formed of an insulating material.

The insulating material may further include carbon black.

The touch sensor may further include: an electrode pattern formed at an inner side of the window substrate; and an electrode wiring formed on the bezel layer for electrical connection of the electrode pattern.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a touch sensor according to a preferred embodiment of the present invention in which a bezel layer is formed along the edge of a window substrate;

FIG. 2 is a cross-sectional view of a touch sensor according to a preferred embodiment of the present invention in which a window substrate is coupled with a base substrate including an electrode pattern;

FIG. 3 is a cross-sectional view of a touch sensor according to another preferred embodiment of the present invention in which electrode pattern formed at the inner side of the window substrate and electrode wiring formed on the bezel layer for electrical connection are included; and

FIG. 4 is a cross-sectional view of a typical window-integrated touch sensor according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

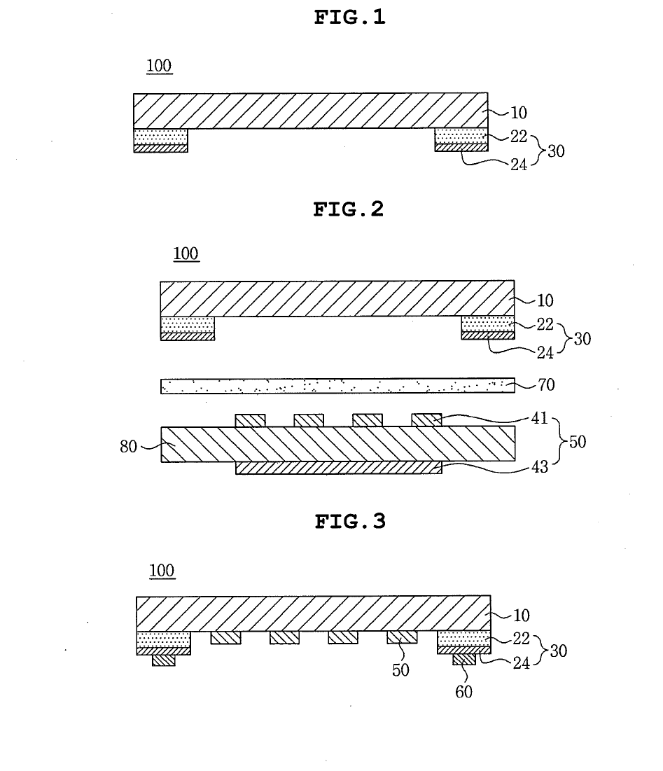

FIG. 1 is a cross-sectional view of a touch sensor according to a preferred embodiment of the present invention in which a bezel layer is formed along the edge of a window substrate. Referring to FIG. 1, the touch sensor 100 according to the preferred embodiment of the present invention may include a window substrate 10 and a bezel layer 30 formed along the edge of the window substrate 10, wherein the bezel layer 30 may include a print layer 22 and a shield layer 24, wherein the print layer 22 may include titanium dioxide TiO₂ of 60 to 95 weight %.

In the touch sensor 100 according to the preferred embodiment of the present invention, the window substrate 10 may be formed of reinforce glass or the like so that it is transparent while protecting the touch sensor 100 from impact from the outside. The various types of substrates may be selected by those skilled in the art in view of transparency and rigidity.

In the touch sensor 100 according to the preferred embodiment of the present invention, the bezel layer 30 may include the print layer 22 and the shield layer 24 and may be formed along the edge of the window substrate 10.

The print layer 22 may include titanium dioxide TiO₂ of 60 to 95 weight % so as to form a white bezel layer 30. The titanium dioxide TiO₂ has a very large refractive index and is good at exhibiting white color. If the content of the titanium dioxide TiO₂ is less than 60 weight %, the bezel layer fails to exhibit whiteness sufficiently. If the content of the titanium dioxide TiO₂ is greater than 95 weight %, the physical property of the print layer 22 is deteriorated, so that rigidity of the print layer is significantly lowered and thus the bezel layer 30 may not be normally formed.

In order to improve dispersibility and further increase the effect of blocking ultraviolet rays, particle surfaces of the titanium dioxide TiO₂ may be coated with silica SiO₂, aluminum oxide Al₂O₃, zirconium oxide ZrO₂, zinc oxide ZnO or a mixture thereof.

The print layer 22 may have a thickness less than 20 μm so as to implement thin-film touch sensor 100. Since the thickness of the print layer included in the bezel layer of conventional touch sensors is relatively thick and a number of print layers are stacked, the process is so complicated that the defect rate is high, it is difficult to make electrical connection because of level differences, and the touch sensor is not sufficiently thinned.

In the touch sensor 100 according to the preferred embodiment of the present invention, however, the print layer 22 may be single-layered or two-layered by a screen printing method. In addition, the print layer 22 may have a thickness less than 20 μm because it may exhibit sufficient whiteness by including the titanium dioxide TiO₂. By doing so, the number of printing is reduced more than in the prior art, and thus processing cost may be saved along with the defect rate.

The whiteness of the print layer 22 refers to luminance L* in the L*a*b color space. The L*a*b color space is a color space adopted by the International Commission on Illumination (CIE) in 1976, in which L* denotes luminance (brightness), a* denotes color, and b* denotes chroma. In the touch sensor 100 according to the preferred embodiment of the present invention, the luminance L* may be 80% or higher.

The numeral value may be achieved by including titanium dioxide TiO₂ of 60 to 95 weight % in the print layer 22. The touch sensor 100 according to the preferred embodiment of the present invention may include, most preferably, titanium dioxide TiO₂ of 75 to 90 weight % in the print layer 22 in order to obtain sufficient whiteness and to form a normal bezel layer. In this case, the luminance L* may be 83% or higher.

The print layer 22 may include a thermosetting resin or a photo-curable resin of 5 to 40 weight %. The thermosetting resin or photo-curable resin may use, but is not limited to, an epoxy based resin, a polyester based resin, a maleimide based resin, a cyanate based resin, a phenol based resin, a melamine based resin, an acryl based resin, an acrylate based resin, polyamaide based resin, and a urea resin.

Further, the print layer 22 may further include a whitening agent. The whitening agent absorbs ultraviolet rays to make the print layer 22 look whiter and may include, but is not limited to, imidazole derivatives, coumarin derivatives, pyrazolin derivatives, methyne compounds, and naphthalimide derivatives.

In the touch sensor 100 according to a preferred embodiment of the present invention, the print layer 22 may further include the shield layer 24 formed thereon in order to improve the effect of completely reflecting or blocking light from the outside by the bezel layer 30.

The shield layer 24 may be formed of an insulating material. The insulating material may include a typical organic or inorganic insulating material and may be manufactured through printing, chemical vapor deposition (CVD), sputtering or the like.

Further, the shield layer 24 may include black-series carbon black in addition to a thermosetting or thermoplastic resin in order to absorb ultraviolet rays or light transmitting the print layer 22. However, the present invention is not limited thereto.

In the touch sensor 100 according to a preferred embodiment of the present invention, prior to forming the bezel layer 30, an additional organic or inorganic film may be applied onto the window substrate 10 for decoration. The organic film may be formed of, but is not limited to, an ink consisting of pearl and a transparent resin, and the inorganic film may be formed of, but is not limited to, titanium Ti, silica SiO₂, or titanium dioxide TiO₂.

FIG. 2 is a cross-sectional view of a touch sensor according to a preferred embodiment of the present invention in which a window substrate is coupled with a base substrate including electrode patterns. Referring to FIG. 2, as is appreciated, the touch sensor 100 according to the preferred embodiment of the present invention may be implemented by forming first electrode patterns 41 and second electrode patterns 43 intersecting each other on both surfaces of the base substrate 80 coupled with the window substrate 10. The first electrode patterns 41 and the second electrode patterns 43 are formed on both surfaces of the base substrate 80 and the base substrate 80 may be coupled with the window substrate 10 by an adhesive layer 70.

The base substrate 80 may be formed of a transparent material. The material is not particularly limited as long as it has a certain minimum strength and may include, but not limited to, polyethylene terephthalate (PET), polycarbonate (PC), poly methyl methacrylate (PMMA), polyethylene naphthalate (PEN), polyethersulfone (PES), cyclic olefin polymer (COC), triacetylcellulose (TAC) film. Further, high-frequency treatment or primer treatment may be performed on one surface of the base substrate 80 so that the adhesive strength with the electrode patterns 50 may be enhanced.

The adhesive layer 70 may be formed of a transparent material so as not to obstruct a user to view images displayed on the display unit 90. The material of the adhesive layer 70 may include, but is not limited to, an optical clear adhesive (OCA) or a double adhesive tape (DAT).

FIG. 3 is a cross-sectional view of a touch sensor according to another preferred embodiment of the present invention in which electrode pattern formed at the inner side of the window substrate and electrode wiring formed on the bezel layer for electrical connection are included. Referring to FIG. 3, the touch sensor 100 according to another preferred embodiment of the present invention is integrated with a window and may include electrode patterns 50 formed at the inner side of the window substrate 10 and electrode wiring 60 formed on the bezel layer 30 for electrical connection.

The window substrate 10 provides an area in which the electrode patterns 50 and the electrode wiring 60 are formed. The window substrate 10 is divided into an active region and a bezel region. The active region is provided at the inner side of the window substrate 10, in which electrode patterns 50 are formed so that a touch by input means is sensed. The bezel region is provided along the edge of the window substrate 10, in which the electrode wiring 60 is formed that is electrically connected to the electrode pattern 50. The window substrate 10 needs to be capable of supporting the electrode patterns 50 and the electrode wirings 60 while be transparent so that a user can recognize images displayed on an image display device.

Further, in the touch sensor integrated with the window, the electrode patterns 50 are directly formed on the window substrate 10, including a structure in which the electrode patterns 50 are directly formed on the window substrate 10 having an additional layer such as a separate adhesive layer 70 formed thereon. However, the structure of the touch sensor 100 according to another preferred embodiment of the present invention is not particularly limited thereto.

In the touch sensor 100 according to another preferred embodiment of the present invention, the electrode pattern 50 may generate a signal if a user touches to allow a controller to recognize coordinate of the touch.

Here, the electrode patterns 50 may be formed in a mesh pattern using copper (Cu), aluminum (Al), gold (Au), silver (Ag), titanium (Ti), palladium (Pd), chromium (Cr), or a combination thereof. In this case, the electrode pattern 50 may be formed by a plating process or a depositing process using a sputter.

When the electrode pattern 50 is made of copper (Cu), the surfaces of the electrode patterns 50 may be black-oxide treated to make the electrode patterns 50 less visible. Here, the black-oxide treatment indicates treatment in which copper-oxide (I) Cu₂O or CuO is precipitated by oxidizing the surface of the electrode pattern 50, wherein copper-oxide (I) Cu₂O is brown and is thus referred to as a brown oxide and the CuO is black and is thus referred to as a black oxide.

As described above, the surfaces of the electrode patterns 50 are black-oxidized to prevent light from being reflected, thereby improving visibility of the touch sensor 100.

In addition to those metals described above, the electrode patterns 50 may also be formed using metal silver formed by exposing/developing a silver salt emulsion layer, a metal oxide such as an indium tin oxide (ITO) or the like, a conductive polymer such as poly-3,4-ethylenedioxythiophene/polystyrenesulfonate (PEDOT/PSS), having excellent flexibility and a simple coating process. However, the present invention is not limited thereto.

The electrode patterns 50 may be formed in any pattern known in the art, such as a diamond pattern, a rectangular pattern, a triangular pattern, or a circular pattern.

In the touch sensor 100 according to another preferred embodiment of the present invention, the electrode wiring 60 may receive an electrical signal from the electrode patterns 50. The electrode wiring 60 may be integrated with the first electrode pattern 41 of the electrode pattern 50 and the second electrode pattern 43 of the electrode pattern 50, so that a manufacturing process becomes simpler and the lead time may be shortened. In addition, the electrode wiring 60 and the electrode pattern 50 may be integrated so that bonding process of the electrode wiring 60 and the electrode pattern 50 may be omitted. Therefore, by making the thickness of the print layer less than 20 μm, a level difference or bonding failure between the electrode wiring 60 and the electrode patterns 50 may be prevented.

The electrode wiring 60 may be printed by using screen printing, gravure printing or inkjet printing. The material for the electrode wiring 60 may include, but is not limited to, Ag paste having good electrical conductivity or a material composed of organic silver.

In addition, the electrode wiring 60 may be formed of indium tin oxide (ITO), PEDOT/PSS, carbon nanotube (CNT), graphene, zinc oxide (ZnO) or Al-doped zinc oxide (AZO).

Although the electrode wiring 60 is connected to both terminals of the electrode patterns 50 in the drawing, it is apparent that the electrode wiring 60 may be connected to one terminal of the electrode patterns 50 depending on the type of the touch sensor 100.

Descriptions on the window substrate 10, and the bezel layer 30 including the print layer 22 and the shield layer 24 are substantially identical to those described with respect to the touch sensor 100 in FIG. 1, and, therefore, will not be repeated.

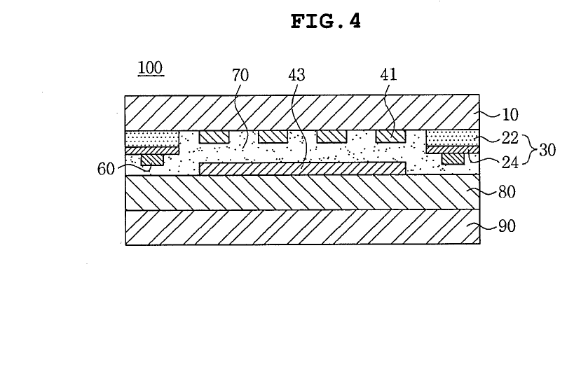

FIG. 4 is a cross-sectional view of a typical window-integrated touch sensor according to a preferred embodiment of the present invention. Referring to FIG. 4, the touch sensor 100 according to the preferred embodiment of the present invention may include the first electrode pattern 41 of the electrode patterns 50 formed at the inner side of the window substrate 10 and the electrode wiring 60 formed on the bezel layer 30 for electrical connection. In addition, the base substrate 80 on which the second electrode pattern 43 is formed may be formed with the adhesive layer 70 such that the first electrode pattern 41 and of the electrode pattern 50 and a second electrode pattern 43 face each other.

Further, a display unit 90 may be formed under the base substrate 80. Although not shown in the drawing, another adhesive layer 70 may be formed between the base substrate 80 and the display unit 90.

The display unit 90 displays an image and may include a liquid crystal display device (LCD), a plasma display panel (PDP), an electroluminescence (EL) or a cathode ray tube (CRT).

Descriptions on the window substrate 10, and the bezel layer 30 including the print layer 22 and the shield layer 24 are substantially identical to those described with respect to the touch sensor 100 in FIG. 1, and, therefore, will not be repeated.

In the touch sensor 100 according to a preferred embodiment of the present invention, an example for measuring whiteness by forming a bezel layer is as follows. 80 g of Titanium dioxide TiO₂ having silica SiO₂ and aluminum oxide Al₂O₃ coated thereon, 16 g of polyol which is an ester-based resin, 3 g of isocyanate hardner, 30 g of isophorone solution, 0.8 g of dispersant PB821, 0.3 g of deformer BYK057, and 0.3 g of leveling agent BYK 361n are mixed to produce a composition, and the composition is printed on a glass substrate twice by screen printing to produce a print layer having a thickness of 18 μm. Then, a shield film is formed with a black ink on the print layer to produce a bezel layer. Then, whiteness was measured on the glass surface using a spectrophotometer (Konica Minolta CM-2600d) to obtain a result of 83%.

As set forth above, according to the present invention, titanium dioxide TiO₂ of from 60 to 95 weight % is included in the print layer, which is an element of the bezel layer of the touch sensor, so that whiteness may be improved.

Further, the thickness of the print layer is 20 μm or less, so that difficulty in forming electrical connection due to a level difference may be overcome

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A touch sensor, comprising:
a window substrate; and
a bezel layer formed along an edge of the window substrate, wherein the bezel layer includes a print layer and a shield layer,
wherein the print layer includes titanium dioxide TiO₂ of from 60 to 95 weight %.

2. The touch sensor as set forth in claim 1, wherein the print layer includes titanium dioxide TiO₂ of from 75 to 90 weight %.

3. The touch sensor as set forth in claim 1, wherein particle surfaces of the titanium dioxide TiO₂ are coated with silica SiO₂, aluminum oxide Al₂O₃, zirconium oxide ZrO₂, zinc oxide ZnO or a mixture thereof.

4. The touch sensor as set forth in claim 1, wherein the print layer includes a thermosetting resin or a photo-curable resin of 5 to 40 weight %.

5. The touch sensor as set forth in claim 1, wherein a thickness of the print layer is less than 20 μm.

6. The touch sensor as set forth in claim 1, wherein the print layer has luminance L* of 80% or higher in the L*a*b color space adopted by the International Commission on Illumination (CIE).

7. The touch sensor as set forth in claim 1, wherein the print layer further includes a whitening agent.

8. The touch sensor as set forth in claim 1, wherein the shield layer is formed of an insulating material.

9. The touch sensor as set forth in claim 8, wherein the insulating material further includes carbon black.

10. The touch sensor as set forth in claim 1, further comprising: an electrode pattern formed at an inner side of the window substrate; and an electrode wiring formed on the bezel layer for electrical connection of the electrode pattern.
